(19) United States
(12) Patent Application Publication
(10) Pub. No.: US 2026/0031818 A1
(43) Pub. Date: Jan. 29, 2026

(54) SEMICONDUCTOR DEVICE AND COMMUNICATION SYSTEM

(71) Applicant: ROHM CO., LTD., Kyoto (JP)

(72) Inventor: Kei NAGAO, Kyoto (JP)

(21) Appl. No.: 19/272,519

(22) Filed: Jul. 17, 2025

(30) Foreign Application Priority Data
Jul. 24, 2024 (JP) 2024-118477

(51) Int. Cl. H03K 19/0185; G06F 13/40

(52) U.S. Cl. CPC H03K 19/01855; G06F 13/4072; H03K 19/018557

(57) ABSTRACT

In a semiconductor device, a first receiving section and a first transmitting section are configured such that when a bridge selection data included in a reception data indicates that a through-output between a first bus and a second bus is on, data for a first device included in the reception data is through-output from the first output terminal to the second bus; a clock signal output section is configured to output a clock signal synchronized with the through-output data; and a second receiving section is configured to receive an acknowledgment transmitted from the first device via the first input terminal in response to a reception of the through-output data.

### TECHNICAL FIELD

The present disclosure relates to a semiconductor device.

### BACKGROUND

Semiconductor devices comprising serial communication functions are used in various applications.

Furthermore, an example of circuit technology related to serial communication is disclosed in Patent Document 1.

### PRIOR ART DOCUMENT

### Patent Document

[Patent document 1] Japan Patent Publication No. 2017-224946.

### BRIEF DESCRIPTION OF THE DRAWINGS

FIG. 1 is a diagram showing a configuration of a communication system according to a first comparative example.

FIG. 2 is a diagram showing a configuration of a communication system according to a second comparative example.

FIG. 3 is a diagram showing a configuration of a communication system according to an exemplary embodiment of the present disclosure.

FIG. 4 is a block diagram of a semiconductor device according to an exemplary embodiment of the present disclosure.

FIG. 5 is a block diagram of a semiconductor device according to an exemplary embodiment of the present disclosure.

FIG. 6 is a diagram showing a data configuration of reception data RX when a Write or Read is performed with a semiconductor device 1 as a target device.

FIG. 7 is a diagram showing a configuration example of a communication system according to an embodiment of the present disclosure.

FIG. 8 is a diagram showing a data configuration of reception data RX when a Write or Read is performed with a device 10 as a target device.

FIG. 9 is a timing chart showing communication control when a Write is performed on a device 10.

FIG. 10 is a timing chart showing communication control when a Read is performed on a device 10.

FIG. 11A is a diagram showing a configuration example of a communication system according to an embodiment of the present disclosure.

FIG. 11B is a diagram showing a configuration example of a communication system according to a modified example of an embodiment of the present disclosure.

FIG. 12 is a diagram showing a transmission and reception configuration between a semiconductor device 1 and an I2C device 100.

FIG. 13 is a diagram showing a configuration of a signal output section based on a push-pull configuration.

FIG. 14 is a diagram showing a configuration of a signal output section based on an open-drain configuration.

FIG. 15 is a table showing communication method setting information BRIFSEL.

FIG. 16 is a table showing bridge mode information BRMODE.

FIG. 17 is a timing chart showing an example of operation when a Write is performed on an I2C device.

FIG. 18 is a diagram showing a data configuration of reception data RX when a Write or Read is performed with an I2C device as a target device.

FIG. 19 is a timing chart showing an example of operation when a Read is performed on an I2C device.

FIG. 20 is a diagram showing a configuration example of a motor driver.

FIG. 21 is an external view showing an example of a vehicle.

### DETAILED DESCRIPTION OF THE EMBODIMENTS

Hereinafter, exemplary embodiments of the present disclosure are illustrated with reference to figures.

### 1. Communication System

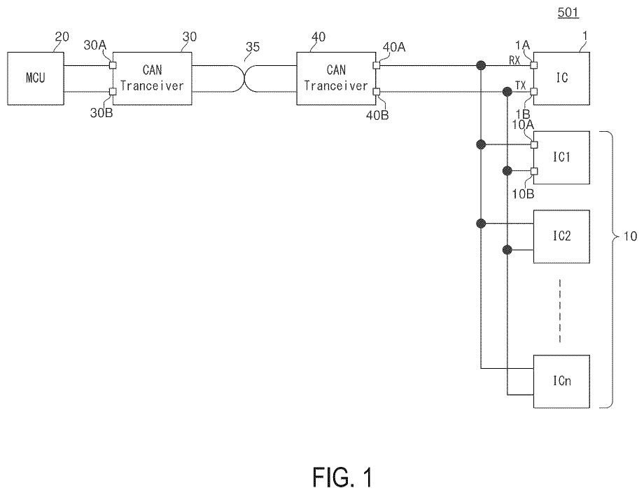

FIG. 1 is a diagram showing a configuration of a communication system 501 according to a first comparative example for comparison with embodiments of the present disclosure. The communication system 501 comprises an MCU (Micro Controller Unit) 20, a CAN (Controller Area Network) transceiver 30, a CAN transceiver 40, a semiconductor device 1, and n (n is an integer of 1 or more) devices 10. Furthermore, a configuration may be adopted in which a CAN transceiver is not provided between the MCU 20 and the semiconductor device 1. The communication system 501 is for in-vehicle use, as an example, and the same applies to other communication systems illustrated below.

Between the MCU 20 and the CAN transceiver 30, communication is conducted using UART (Universal Asynchronous Receiver/Transmitter) as a communication method. UART is a protocol for exchanging serial data between two devices. In UART, bidirectional communication is conducted over two lines between a transmitting side and a receiving side.

Communication between the CAN transceivers 30 and 40 is conducted via a CAN bus 35. CAN is a serial communication protocol standardized in international standards such as ISO 11898. Communication between the CAN transceiver 40, the semiconductor device 1, and the n devices 10 is conducted via UART.

The CAN transceiver 30 comprises a TXD (transmit data input) terminal 30A and an RXD (receive data output) terminal 30B. The CAN transceiver 30 outputs data input to the TXD terminal 30A to the CAN bus 35 and outputs data input from the CAN bus 35 from the RXD terminal 30B.

The CAN transceiver 40 comprises an RXD terminal 40A and a TXD terminal 40B. The CAN transceiver 40 outputs data input to the TXD terminal 40B to the CAN bus 35 and outputs data input from the CAN bus 35 from the RXD terminal 40A.

The semiconductor device 1 is an IC (Integrated Circuit) in which circuits for specific functions are integrated, and is configured, for example, as an LED (Light Emitting Diode) driver IC. The n devices 10 are ICs in which circuits for specific functions are integrated, and are configured as, for example, matrix switch ICs.

The semiconductor device 1 comprises an RX (Receive Data Input) terminal 1A and a TX (Transmit Data Output) terminal 1B. The device 10 comprises an RX terminal 10A and a TX terminal 10B. The RX terminal 1A and the n RX terminals 10A are commonly connected to an RXD terminal 40A. The TX terminal 1B and the n TX terminals 10B are commonly connected to a TXD terminal 40B.

In the first comparative example shown in FIG. 1, since the semiconductor device 1 and the n devices 10 correspond to the same protocol, the semiconductor device 1 and the n devices 10 can be commonly connected to the same CAN transceiver 40. Reception data RX output from the RXD terminal 40A is input to the RX terminal 1A and the n RX terminals 10A. The reception data RX specifies a device address of either the semiconductor device 1 or one of the n devices 10. Additionally, transmission data TX output from the TX terminal 1B and the n TX terminals 10B is input to the TXD terminal 40B.

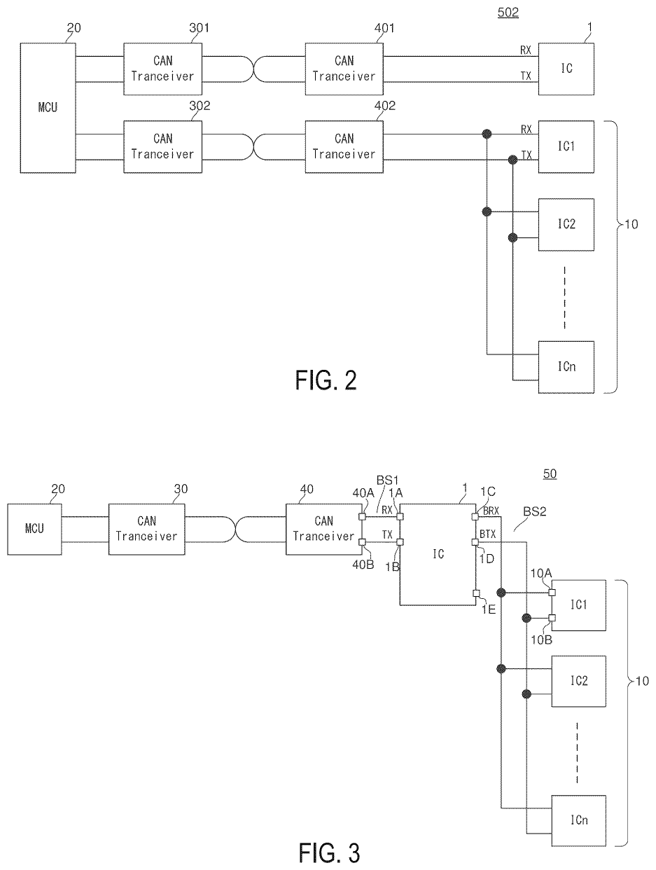

However, if the protocols that the semiconductor device 1 and the n devices 10 correspond to are different, it becomes difficult to accommodate the configuration of the first comparative example as shown in FIG. 1. Thus, in such cases, a configuration of a second comparative example shown in FIG. 2 can be adopted.

A communication system 502 according to the second comparative example shown in FIG. 2 differs from the first comparative example in that CAN transceivers 301 and 302 are used instead of the CAN transceiver 30, and CAN transceivers 401 and 402 are used instead of the CAN transceiver 40. The semiconductor device 1 is connected to the MCU 20 via the CAN transceiver 301 and the CAN transceiver 401, and the n devices 10 are connected to the MCU 20 via the CAN transceiver 302 and the CAN transceiver 402. The CAN transceivers 401, 402 each conducts CAN communication with CAN transceivers 301, 302, respectively.

As such, by grouping devices having different protocols (a group of semiconductor device 1 and a group of n devices 10), communication control can be performed using devices having different protocols. However, as a number of CAN transceivers, such as the CAN transceivers 301, 302, 401, 402, increases, an amount of wiring increases, leading to an issue of rising costs.

Therefore, to solve such issues, embodiments of the present disclosure are implemented as illustrated below. FIG. 3 is a diagram showing a configuration of a communication system 50 according to an exemplary embodiment of the present disclosure.

In the configuration shown in FIG. 3, communication via UART is conducted between the CAN transceiver 40, the semiconductor device 1, and the n devices 10. The semiconductor device 1 comprises an RXD (Reception Data Output) terminal 1C and a TXD (Transmission data Input) terminal 1D in addition to the RX terminal 1A and the TX terminal 1B. The RX terminal 1A is connected to the RXD terminal 40A of the CAN transceiver 40. The TX terminal 1B is connected to the TXD terminal 40B of the CAN transceiver 40. That is, the RX terminal 1A and the TX terminal 1B are connected to the RXD terminal 40A and the TXD terminal 40B via a bus BS1. Communication of the reception data RX and the transmission data TX is possible via the bus BS1. The reception data RX and the transmission data TX are serial data.

The RXD terminal 1C is connected to the RX terminal 10A of the n devices 10. The TXD terminal 1D is connected to the TX terminal 10B of the n devices 10. That is, the RXD terminal 1C and the TXD terminal 1D are connected to the RX terminal 10A and the TX terminal 10B via a bus (local bus) BS2. Communication of reception data BRX and transmission data BTX is possible via the bus BS2. The reception data BRX and the transmission data BTX are serial data.

Furthermore, the semiconductor device 1 also comprises an SCL terminal (clock terminal) 1E. As described below, the SCL terminal 1E is a terminal for outputting a clock signal. The terminal 1E is used when a device corresponding to 12C (Inter Integrated Circuit) as a communication method is employed, as described below, and when the device 10 corresponding to UART is employed, as shown in FIG. 3, the terminal 1E is not used.

In a configuration according to an embodiment of the present disclosure shown in FIG. 3, the semiconductor device 1 and the n devices 10 correspond to different protocols. When the CAN transceiver 40 performs a Write or Read with respect to the semiconductor device 1, the reception data RX output from the RXD terminal 40A to the RX terminal 1A consists only of data corresponding to the protocol of the semiconductor device 1. Furthermore, Write is a process of writing data to a target device, and Read is a process of reading data from the target device. In a case of Read, after receiving the reception data RX, the semiconductor device 1 outputs the transmission data TX from the TX terminal 1B to the TXD terminal 40B.

On the other hand, when the CAN transceiver 40 performs a Write or Read with respect to the device 10, the reception data RX output from the RXD terminal 40A to the RX terminal 1A includes data corresponding to a protocol of the device 10. At this time, the semiconductor device 1 turns on the bridge function and through-outputs data corresponding to the protocol of the device 10 included in the reception data RX as reception data BRX from the RXD terminal 1C. Through-output means outputting bit data as is. A device address of the device 10 is specified for the reception data BRX.

In the case of Read, the device 10, which is the target device (specified by the device address), outputs the transmission data BTX from the TX terminal 10B to the TXD terminal 1D. Since the bridge function is on, the semiconductor device 1 through-outputs the transmission data BTX as transmission data TX from the TX terminal 1B.

As such, according to the embodiment of the present disclosure, even if the protocols of the semiconductor device 1 and the device 10 are different, the CAN transceiver 40 can perform Write and Read on the semiconductor device 1 and the device 10, respectively. Compared to the second comparative example (FIG. 2), the number of CAN transceivers can be reduced, and the amount of wiring can be decreased, thereby reducing costs.

### 2. Configuration of Semiconductor Device

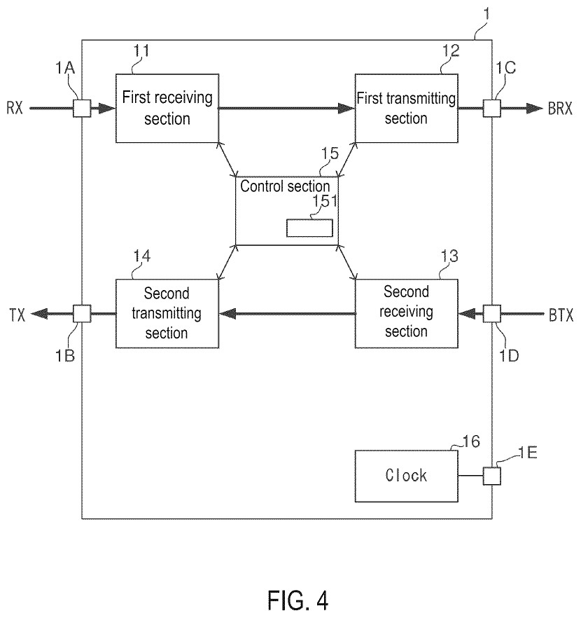

FIG. 4 is a block diagram of a semiconductor device 1 according to an embodiment of the present disclosure. The semiconductor device 1 comprises, as functional blocks, a first receiving section 11, a first transmitting section 12, a second receiving section 13, a second transmitting section 14, and a control section 15. Furthermore, FIG. 4 illustrates only functional blocks related to communication functions, and may comprise other functional blocks. For example, if the semiconductor device 1 is an LED driver, it may comprise block functions related to LED driving.

The first receiving section 11 receives the reception data RX via the RX terminal 1A. The first transmitting section 12 outputs the reception data BRX via the RXD terminal 1C. The second receiving section 13 receives the transmission data BTX via the TXD terminal 1D. The second transmitting section 14 outputs the transmission data TX via the TX terminal 1B.

The control section 15 controls the first receiving section 11, the first transmitting section 12, the second receiving section 13, and the second transmitting section 14. The control section 15 comprises a register 151.

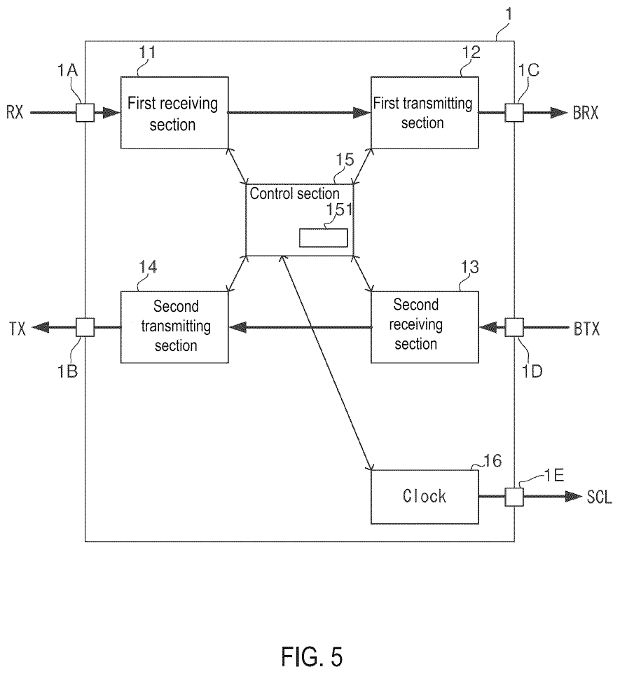

Furthermore, as shown in FIG. 4, the semiconductor device 1 also comprises a clock signal output section 16. FIG. 4 is a diagram showing a state of the semiconductor device 1 when the device 10 corresponding to UART is used, as shown in FIG. 3. The clock signal output section 16 is not used in the state shown in FIG. 4. On the other hand, FIG. 5 is a diagram showing a state of the semiconductor device 1 when a device corresponding to I2C is employed as described below. As shown in FIG. 5, the clock signal output section 16 outputs a clock signal SCL via the SCL terminal 1E. The clock signal SCL is a necessary signal for communication via I2C and is used together with the reception data BRX and transmission data BTX.

### 3. Configuration of Reception Data

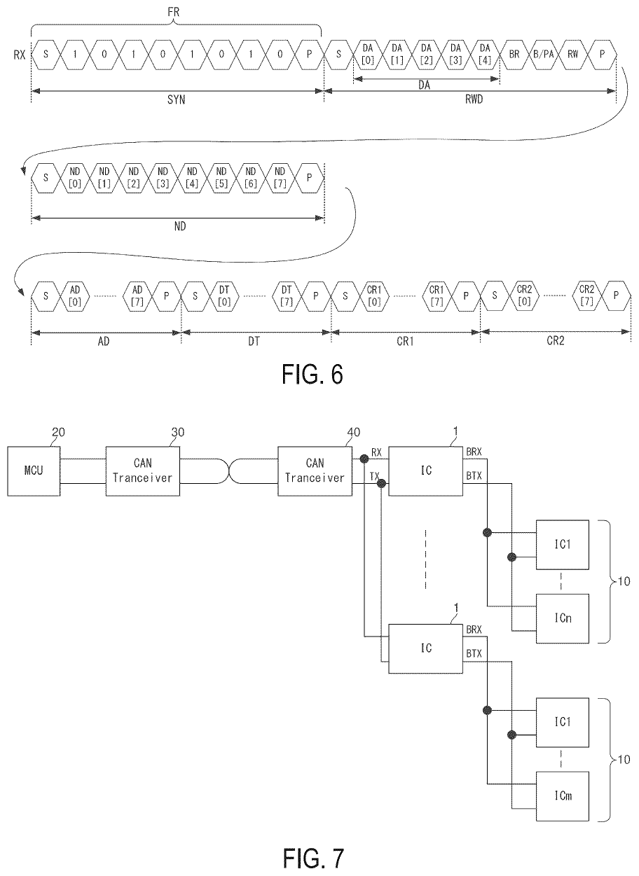

FIG. 6 is a diagram showing a data configuration of the reception data RX when a Write or Read is performed with the semiconductor device 1 as the target device. The reception data RX shown in FIG. 6 consists only of data corresponding to the protocol of the semiconductor device 1.

In UART, communication is conducted using data units called frames. As shown in FIG. 6, a frame FR comprises bit data from a start bit S to a stop bit P. The start bit S is at a low level, and the stop bit P is at a high level. Between the start bit S and the stop bit P, a predetermined number of bits of bit data are arranged. In an example of FIG. 6, 8 bits of bit data are arranged. That is, the frame FR comprises 10 bits of bit data.

As shown in FIG. 6, the reception data RX comprises, in order from the beginning, a synchronization frame SYN, a Read/Write, etc. frame RWD, a data number frame ND, a register address frame AD, a data frame DT, and CRC (Cyclic Redundancy Check) frames CR1, CR2.

The synchronization frame SYN is bit data for setting a baud rate in the semiconductor device 1.

The Read/Write, etc. frame RWD includes a device address DA, a bridge bit BR, a broadcast/parity bit B/PA, and a Read/Write bit RW. The device address DA is bit data indicating an address of the target device (semiconductor device 1) (5-bit data in the example of FIG. 6). The bridge bit BR is bit data indicating whether a bridge function of the semiconductor device 1 is on or off. The broadcast/parity bit B/PA is bit data indicating whether a broadcast of the semiconductor device 1 is on or off or a parity of the data address DA. The Read/Write bit RW is bit data indicating Read or Write.

Herein, the bridge bit BR=0 indicates that the bridge function is off, i.e., normal mode (in the reception data RX shown in FIG. 6, the bridge function is off). In this case, the broadcast/parity bit B/PA indicates whether the broadcast is on or off. When the broadcast/parity bit B/PA=0, it indicates that broadcast is off; when the broadcast/parity bit B/PA=1, it indicates that broadcast is on.

Furthermore, when the broadcast of the semiconductor device 1 is performed, as shown in FIG. 7, multiple semiconductor devices 1 are connected to the CAN transceiver 40. The device 10 is connected to each of the semiconductor devices 1. When the broadcast is on, all of the multiple semiconductor devices 1 become target devices.

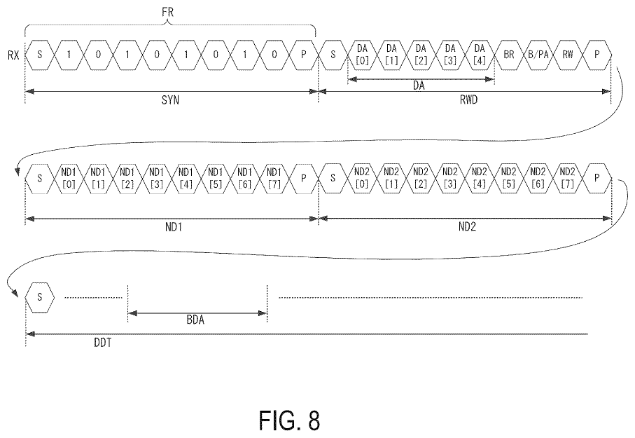

The bridge bit BR=1 indicates that the bridge function is on (in the reception data RX shown in FIG. 8 described below, the bridge function is on). In this case, the broadcast/parity bit B/PA becomes the parity of the device address DA. As a result, error detection of the device address DA can be performed. Furthermore, in a configuration shown in FIG. 7, if the protocols differ for each group of devices 10 connected to each of the multiple semiconductor devices 1, when the broadcast of the semiconductor device 1 is turned on, the same reception data RX would be transmitted as the reception data BRX to the devices 10 having different protocols, resulting in incompatibility with the protocols of some devices 10. Therefore, when the bridge function is on, the broadcast is made not to be performed.

The data number frame ND is bit data indicating a number of frames of the data frame DT. Furthermore, in FIG. 6, as an example, the number of frames of the data frame DT is 1, but it may be 2 or more.

The register address frame AD bit data indicating an address in the register 151. The data frame DT is bit data indicating a main body of data to be transmitted by the reception data RX. Furthermore, in the case of Read, the data frame DT is not included in the reception data RX.

The CRC frames CR1 and CR2 are bit data indicating error detection codes added to the frames RWD, ND, AD, DT as error detection targets. Furthermore, the data frame DT is one frame in the example of FIG. 6, but two or more frames may be included in the reception data RX. In that case, two or more frames of the data frames DT are followed by the CRC frames CR1 and CR2.

FIG. 8 is a diagram showing a data configuration of the reception data RX when a Write or Read is performed with the device 10 as the target device. The synchronization frame SYN and the Read/Write, etc. frame RWD in the reception data RX shown in FIG. 8 are as described above.

In the reception data RX shown in FIG. 8, the Read/Write, etc. frame RWD is followed by a first data number frame ND1 and the second data number frame ND2. The first data number frame ND1 is bit data indicating a total number of frames. The second data number frame ND2 is bit data indicating a number of frames for Write data for the target device (the device 10 when the bridge function is adopted). In the case of a Write process for the target device, a number of frames indicated by the second data number frame ND2 matches a number of frames indicated by the first data number frame ND1. In the case of a Read process for the target device, the number of frames obtained by subtracting the number of frames indicated by the second data number frame ND2 from the number of frames indicated by the first data number frame ND1 becomes a number of frames of data (read data) returned from the target device to the semiconductor device 1.

In the reception data RX shown in FIG. 8, the second data number frame ND2 is followed by device data DDT. The device data DDT is data corresponding to the protocol of the device 10 and is the target for through-output as reception data BRX. The device data DDT includes a device address BDA. The device address BDA indicates the address of the target device, the device 10. A position where the device address BDA is arranged in the device data DDT is a position depending on the protocol of device 10.

### 4. Through-Output Control

Herein, the through-output control by the semiconductor device 1, i.e., the control when the bridge function is on, is described.

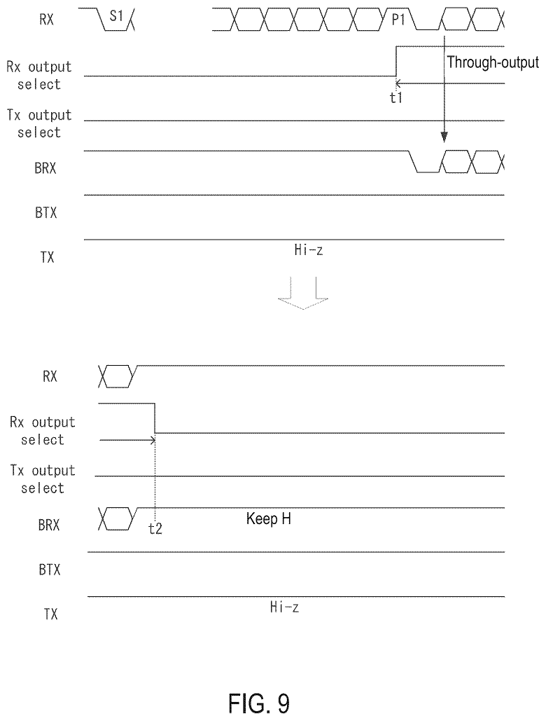

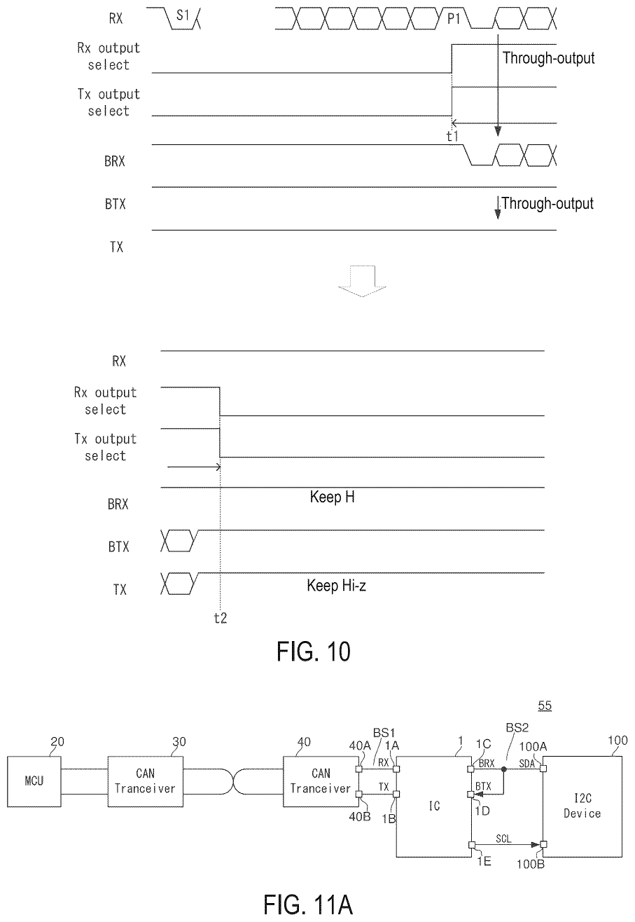

FIG. 9 is a timing chart showing communication control when a Write is performed on the device 10. In order from top of FIG. 9, reception data RX, a reception data output selection signal (RX output select), a transmission data output selection signal (TX output select), reception data BRX, transmission data BTX, and transmission data TX are shown (similarly in FIG. 10). The reception data RX has the configuration shown in FIG. 8.

The reception data RX is received by the first receiving section 11 (FIG. 4). Upon receiving a start bit S1 (low level) at the beginning of the reception data RX, the control section 15 recognizes a start of reception of the reception data RX. Subsequently, the control section 15 recognizes that the bridge function is on by the bridge bit BR included in the reception data RX, and also recognizes that it is Write by the Read/Write bit RW.

Subsequently, when the second data number frame ND2 is received, the control section 15 sets the reception data output selection signal in the register 151 from a low level to a high level at a stop bit P1 of the second data number frame ND2 (timing t1). As a result, the through-output of the reception data RX is started, and the first receiving section 11 and the first transmitting section 12 output the reception data RX as the reception data BRX as is. That is, the through-output of the device data DDT (FIG. 8) is performed.

When the reception data output selection signal becomes high level, the control section 15 starts counting a number of frames of the reception data RX (i.e., a number of frames of the device data DDT). When the counted number of frames reaches a number of frames indicated by the received second data number frame ND2, the control section 15 switches the reception data output selection signal to low level and stops the through-output (timing t2). Thereafter, the reception data BRX is kept at high level. Furthermore, in this case, the number of frames indicated by the second data number frame ND2 matches a number of frames indicated by the first data number frame ND1.

FIG. 10 is a timing chart showing communication control when a Read is performed on the device 10. In this case, the reception data RX has the configuration shown in FIG. 8.

After the start bit S1 (low level) at the beginning of the reception data RX is received, the control section 15 recognizes that the bridge function is on by the bridge bit BR included in the reception data RX, and also recognizes that it is Read by the Read/Write bit RW.

Subsequently, when the second data number frame ND2 is received, the control section 15 sets both the reception data output selection signal and the transmission data output selection signal in the register 151 from a low level to a high level at the stop bit PI of the second data number frame ND2 (timing t1). As a result, the through-output of the reception data RX and the transmission data BTX is started. The first receiving section 11 and the first transmitting section 12 output the reception data RX as the reception data BRX as is, that is, the through-output of the device data DDT (FIG. 8) is performed. After the output of the reception data BRX is completed, the second receiving section 13 and the second transmitting section 14 through-output the transmission data BTX transmitted from the device 10 as the transmission data TX.

When the reception data output selection signal and the transmission data output selection signal become high level, the control section 15 starts counting the number of frames of the reception data RX. When a sum of a number of frames counted for the reception data RX and a number of frames counted for the transmission data BTX that is subsequently received reaches the number of frames indicated by the first data number frame ND1, the control section 15 switches both the reception data output selection signal and the transmission data output selection signal to low level, stopping the through-output (timing t2). Thereafter, the transmission data TX is kept at Hi-Z (high impedance).

As such, in this embodiment, a condition for ending the through-output can be determined based on the number of frames received by the semiconductor device 1. Particularly, according to this embodiment, even if the transmission of the reception data RX from the MCU 20 is interrupted due to interrupt processing in the MCU 20, counting the number of frames does not progress during the interruption, and therefore it is possible to avoid the through-output being interrupted erroneously. That is, since the interruption of through-output can be avoided regardless of interrupt time, it is less subject to restrictions due to specifications of the MCU 20.

### 5. Conversion Between UART and I2C

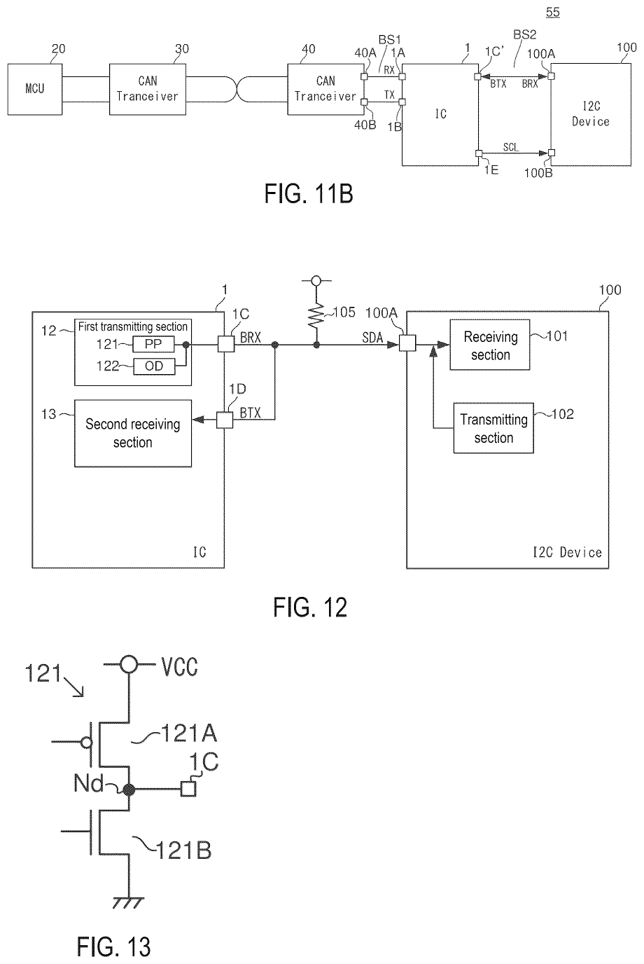

The semiconductor device 1 of this embodiment can also be connected to an external device that corresponds to communication using I2C. FIG. 11A is a diagram showing a communication system 55 comprising the semiconductor device 1 and an I2C device 100 corresponding to I2C. Furthermore, the I2C device 100 is configured as a semiconductor device having various functions, such as a motor driver as described below.

The I2C device 100 comprises an SDA terminal (data terminal) 100A and an SCL terminal (clock terminal) 100B.

The RXD terminal 1C and TXD terminal ID of the semiconductor device 1 are commonly connected to an SDA terminal 100A. Furthermore, the RXD terminal 1C and the TXD terminal 1D are not limited to separate terminals, and may be the same input/output terminal 1C′ as shown in the configuration of FIG. 11B. The reception data BRX output from the RXD terminal 1C is input to the SDA terminal 100A. The transmission data BTX output from the SDA terminal 100A is input to the TXD terminal 1D.

The SCL terminal 1E of the semiconductor device 1 is connected to the SCL terminal 100B. The clock signal SCL output from the SCL terminal 1E is input to the SCL terminal 100B. That is, between the semiconductor device 1 and the I2C device 100, communication is conducted via the second bus BS2 using each of the signals BRX, BTX, SCL.

The semiconductor device 1 operates as a master, and the I2C device 100 operates as a slave. When the reception data BRX is transmitted from the semiconductor device 1 to the I2C device 100, the clock signal SCL is transmitted from the semiconductor device 1 to the I2C device 100. The semiconductor device 1 transmits the reception data BRX in synchronization with the clock signal SCL. The I2C device 100 receives the reception data BRX in synchronization with the clock signal SCL.

Even when data is being transmitted from the I2C device 100 to the semiconductor device 1, the semiconductor device 1 transmits the clock signal SCK to the I2C device 100. The I2C device 100 transmits the transmission data BTX in synchronization with the clock signal SCL. The semiconductor device 1 receives the transmission data BTX in synchronization with the clock signal SCL.

FIG. 12 is a diagram showing a transmission and reception configuration between the semiconductor device 1 and the I2C device 100. A wiring connecting the RXD terminal 1C of the semiconductor layer 1 and the SDA terminal 100A of the I2C device 100 is pulled up by a pull-up resistor 105.

The first transmission unit 12 of the semiconductor device 1 comprises signal output sections 121 and 122. As described below, it is possible to switch which of the signal output sections 121 and 122 is enabled.

As shown in FIG. 13, the signal output section 121 has a push-pull configuration. Specifically, the push-pull configuration comprises a PMOS transistor (P-channel MOSFET) 121A and an NMOS transistor (N-channel MOSFET) 121B connected in series between a power supply voltage VCC application terminal and a ground potential application terminal. A source of the PMOS transistor 121A is connected to the power supply voltage VCC application terminal, and a drain of the PMOS transistor 121A is connected to a drain of the NMOS transistor 121B at a node Nd. A source of the NMOS transistor 121B is connected to the ground potential application terminal. The RXD terminal 1C is connected to the node Nd. By driving the PMOS transistor 121A and the NMOS transistor 121B on and off, high-level or low-level reception data BRX is output from the RXD terminal 1C.

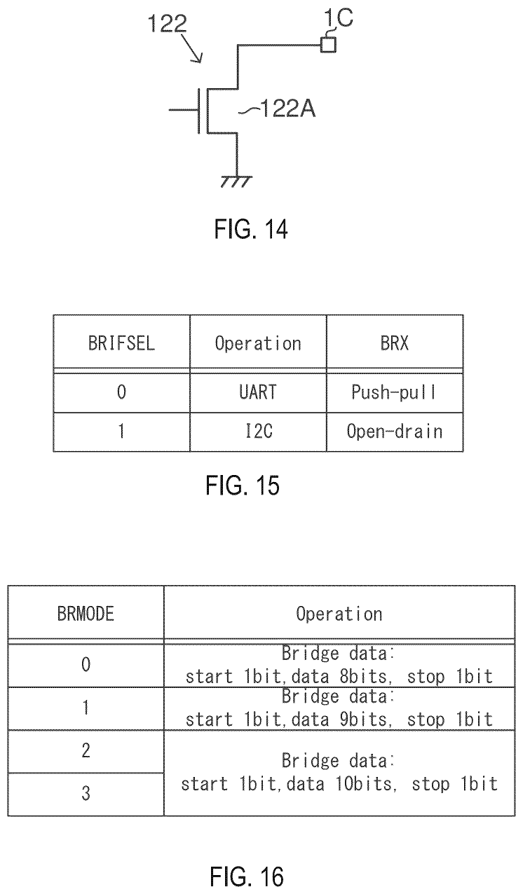

On the other hand, the signal output section 122 has an open-drain configuration using an NMOS transistor 122A, as shown in FIG. 14. A drain of the NMOS transistor 122A is connected to the RXD terminal 1C, and a source of the NMOS transistor 122A is connected to the ground potential application terminal. When the NMOS transistor 122A is driven to the on state, the RXD terminal 1C is set to a low level, and when the NMOS transistor 122A is in the off state, the RXD terminal 1C becomes Hi-Z.

The I2C device 100 comprises a receiving section 101 and a transmitting section 102, each connected to the SDA terminal 100A. The receiving section 101 receives the reception data BRX output from the RXD terminal 1C via the SDA terminal 100A. The transmitting section 102 transmits the transmission data BTX to the second receiving section 13 via the SDA terminal 100A.

As shown in FIG. 12, when the semiconductor device 1 is connected to the I2C device 100, the signal output section 122 having an open-drain configuration becomes effective. When the reception data BRX is transmitted from the signal output section 122, the SDA terminal 100A is set to Hi-Z by an unillustrated signal output section (open-drain configuration) in the transmitting section 102. On the other hand, when the transmission data BTX is transmitted from the transmitting section 102, the RXD terminal 1C is set to Hi-Z by the signal output section 122.

Next, an operation of the communication system 55 (FIG. 11A) having such a configuration is illustrated in more detail. Herein, communication method setting information BRIFSEL as shown in FIG. 15 can be set in the register 151 of the semiconductor device 1. The communication method setting information BRIFSEL indicates the communication method corresponding to the device connected to the semiconductor device 1. In the example of FIG. 15, the communication method setting information BRIFSEL=0 indicates UART, and BRIFSEL=1 indicates I2C. For example, when a device 10 (FIG. 3) corresponding to UART is connected, BRIFSEL=0 is set, and when an I2C device 100 (FIG. 11A) is connected, BRIFSEL=1 is set. The operation is switched according to the setting of BRIFSEL. Specifically, as shown in FIG. 15, when BRIFSEL=0, the previously described signal output section 121 (push-pull configuration) is enabled for transmitting the reception data BRX, and when BRIFSEL=1, the previously described signal output section 122 (open-drain configuration) is enabled.

Furthermore, various settings using communication method setting information BRIFSEL, etc. are not limited to settings in registers; they can also be performed, for example, by resistors, etc. which are connected to an outside of the semiconductor device.

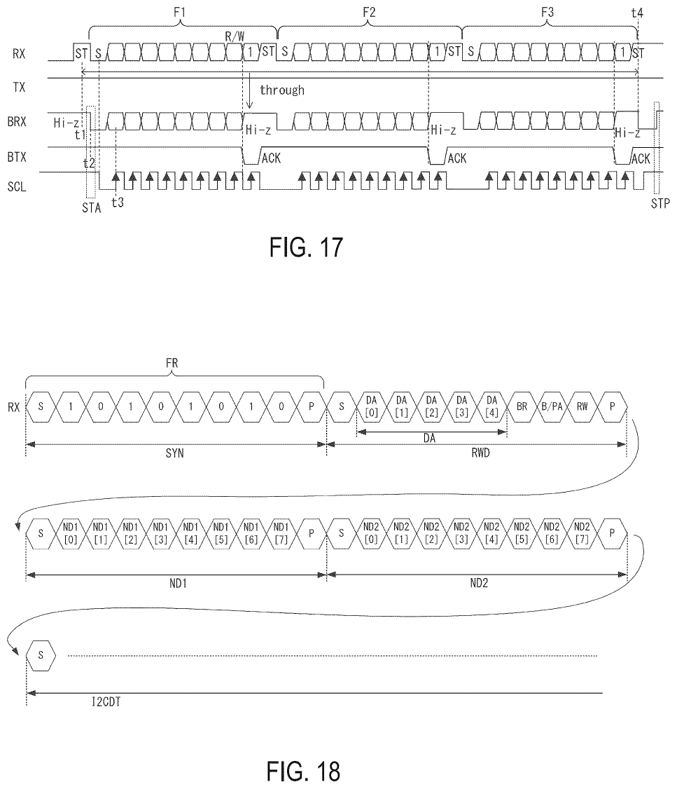

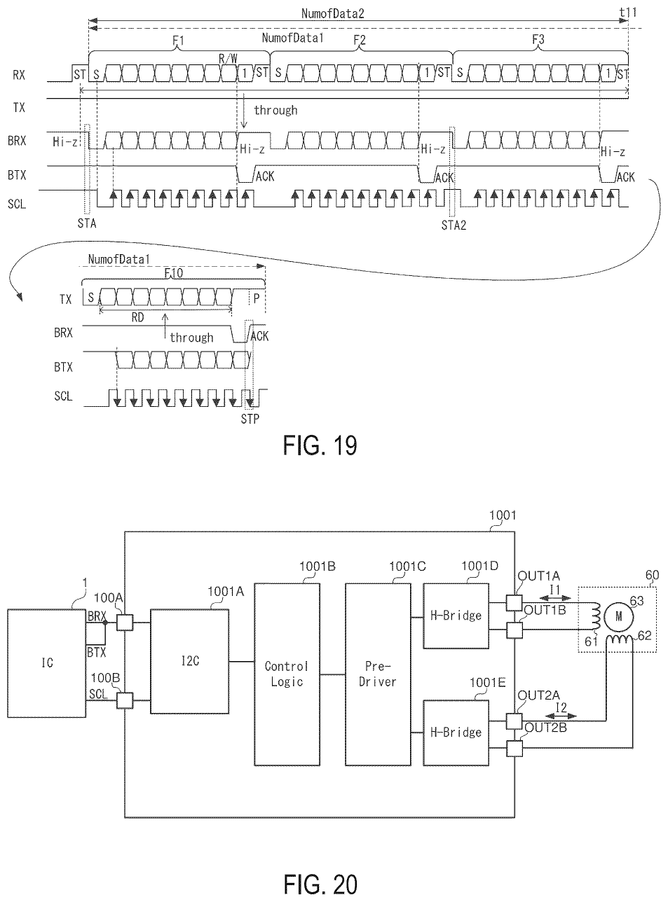

The operation when performing a Write to the I2C device 100 is illustrated with reference to a timing chart shown in FIG. 17. In FIG. 17 (and FIG. 19 described below), in order from top, each waveform example for reception data RX, transmission data TX, reception data BRX, transmission data BTX, and clock signal SCL is shown. However, the reception data BRX and the transmission data BTX actually comprise the same waveform, but the reception data BRX is illustrated as a signal from the semiconductor device 1 to the I2C device 100, and the transmission data BTX is illustrated as a signal from the I2C device 100 to the semiconductor device 1.

Herein, as shown in FIG. 18, the reception data RX includes a synchronization frame SYN, a Read/Write, etc. frame RWD, a first data number frame ND1, and a second data number frame ND2, similar to FIG. 8. In the reception data RX shown in FIG. 18, data I2CDT for the I2C device 100 is included after the second data number frame ND2.

After a start bit (low level) at the beginning of the reception data RX is received, the control section 15 recognizes that the bridge function is on by the bridge bit BR included in the reception data RX, and also recognizes that it is Write by the Read/Write bit RW.

Subsequently, when the second data number frame ND2 is received, the control section 15 starts the through-output of the reception data RX at a stop bit ST of the second data number frame ND2 (timing t1). As a result, the data I2CDT is through-output to the I2C device 100 as the reception data BRX.

After the timing t1, at timing t2, the reception data BRX falls, and since the clock signal SCL is at a high level at this time, a start condition STA is transmitted to the I2C device 100. That is, the start condition is generated at a first frame F1 of the data I2CDT that is through-output from the reception data RX.

Subsequently, the clock signal SCL is output so that a rising edge matches a center of each bit (bits sandwiched between a start bit and a stop bit) of the transmission data BRX that has through-output data I2CDT (timing t3, etc.).

In the example of FIG. 17, a number of bits of data bits between the start bit S and the stop bit ST in one frame of the data I2CDT is set to 9 bits. In this embodiment, the number of bits of data bits between the start bit S and the stop bit ST in one frame of such data I2CDT can be set in the register 151 of the semiconductor device 1. FIG. 16 shows bridge mode information BRMODE, which is setting information for such corresponding bit numbers. The bridge mode information BRMODE is used to detect a length of one frame of the data I2CDT. In the example of FIG. 16, the bridge mode information BRMODE is 2-bit data, and the number of bits of data bits is set according to a value of BRMODE. In the example of FIG. 16, when BRMODE=0, the number of bits=8 bits is set; when BRMODE=1, the number of bits=9 bits is set; and when BRMODE=2 or 3, the number of bits=10 bits is set.

In the example of FIG. 17, the data I2CDT includes three frames F1, F2, and F3. Herein, since the number of frames indicated by the second data number frame ND2 is “3,” it includes three frames F1, F2, and F3. Furthermore, in the case of Write, the number of frames indicated by the second data number frame ND2 matches the number of frames indicated by the first data number frame ND1.

The first frame F1 is a frame for communication of a slave address (an address of the I2C device). In the frame F1, bit R/W, the last bit of the front 8 bits among data bits, represents Read or Write. In the case of FIG. 17, the bit R/W represents Write. The frames F2 and F3 following the frame F1 are frames for data communication.

In any of the frames F1, F2, F3, the last bit of the data bits is set to “1.” As a result, the transmission data BRX from the signal output section 122 (open-drain configuration) is set to Hi-Z. This is to enable reception of an acknowledgment ACK by the transmission data BTX transmitted from the transmission section 102. The acknowledgment ACK is data transmitted from the transmission section 102 as a response to the reception of a predetermined number of bits (8 bits in FIG. 17) in the transmission data BRX and is transmitted as a low-level signal. If the second reception section 13 can receive the acknowledgment ACK, it is in a normal state; if the second reception section 13 cannot receive the acknowledgment ACK, it is in an anomalous state, so the control section 15 stores data indicating the anomalous state in the register 151.

When the number of frames of the reception data RX that is through-output reaches the number of frames indicated by the second data number frame ND2 (which is “3” in the example of FIG. 17), the through-output is stopped by the control section 15 (timing t4). At this time, the transmission data BRX is set to a low level and then rises (timing t5). At this time, since the clock signal SCL is at a high level, a stop condition STP is transmitted to the I2C device 100. That is, the stop condition is generated after the final frame F3.

Next, an operation when performing a Read on the I2C device 100 is illustrated with reference to a timing chart shown in FIG. 19.

As in the case of Write, a start condition STA is generated at a first frame F1, and frames F1, F2, F3 are through-output as transmission data BRX. The bit R/W in the first frame F1 represents Read. Additionally, in the frame whose frame number is indicated by the second data number frame ND2 (frame F3 in FIG. 19), the transmission data BRX falls, and since the clock signal SCL is at a high level, a start condition STA2 is generated.

When the number of frames of the reception data RX that is through-output reaches the number of frames indicated by the second data number frame ND2 (which is “3” in the example of FIG. 19), the through-output is stopped by the control section 15 (timing t11).

Herein, the reception data BRX is set to Hi-Z, and a start bit S is generated in the transmission data TX. Subsequently, the clock signal SCL is generated so that the transmission data BTX can be output at a falling edge. The transmission data BTX is output for 8 bits (a value of the first bit is determined at the falling edge of the last clock SCL in the frame F3), and the 9th bit of the transmission data BTX is set to Hi-Z. This is to output an acknowledgment ACK by the reception data BRX.

The 9 bits of the transmission data BTX are through-output as the transmission data TX, and then a stop bit P is added to the transmission data TX. As a result, a frame F10 including 8 bits of read data RD is transmitted as transmission data TX. When a number of frames obtained by subtracting a number of frames NumofData2 indicated by the second data number frame ND2 from a number of frames NumofData1 indicated by the first data number frame ND1 (4−3=1 in the example of FIG. 19) is read as transmission data TX, the process is completed. Furthermore, at a final frame in the number of frames subtracted above, since the clock signal SCL is at a high level when the transmission data BRX rises, a stop condition STP is generated.

As such, according to the semiconductor device 1 of this embodiment, conversion between UART format and I2C format is possible, and the MCU 20 can perform a Write or Read on the I2C device 100 via the semiconductor device 1. Additionally, there is no need to separately provide a master device for I2C communication with the I2C device 100.

### 6. Application Example

Next, a motor driver as a specific example of the I2C device 100 according to this embodiment is illustrated. FIG. 20 is a diagram showing a schematic configuration of a motor driver 1001.

The motor driver 1001 is configured to drive a two-phase excitation type stepping motor 60 (hereinafter simply referred to as a motor 60). The motor 60 comprises an excitation coil 61 for the first excitation phase, an excitation coil 62 for the second excitation phase, and a rotor 63. During a rotational drive of the motor 60, drive currents I1 and I2 are respectively supplied to the excitation coils 61 and 62 from the motor driver 1001.

The motor driver 1001 integrates and comprises an I2C communication section 1001A, a control logic section 1001B, a pre-driver 1001C, a half-bridge 1001D, and a half-bridge 1001E. Additionally, the motor driver 1001 comprises an SDA terminal 100A and an SCL terminal 100B as external terminals for establishing electrical connections with the outside. Moreover, the motor driver 1001 comprises output terminals OUT1A, OUT1B, OUT2A, OUT2B as external terminals.

The I2C communication section 1001A conducts communication via I2C with the semiconductor device 1. That is, as shown in FIG. 20, communication is conducted using reception data BRX, transmission data BTX, and clock signal SCL. As described above, since the semiconductor device 1 performs conversion between UART and I2C, the I2C communication section 1001A can conduct communication with an unillustrated MCU via the semiconductor device 1. By comprising the I2C communication section 1001A, it is possible to perform various settings for the motor driver 1001, output the state of the motor driver 1001 to the outside, etc.

The control logic section 1001B controls the entire motor driver 1001. The pre-driver 1001C drives the half-bridge 1001D and 1001E under a control of the control logic section 1001B. The half-bridge 1001D controls the drive current I1 by generating voltage signals at the output terminals OUT1A and OUT1B. The half-bridge 1001E controls the drive current I2 by generating voltage signals at the output terminals OUT2A and OUT2B.

### 7. Vehicle

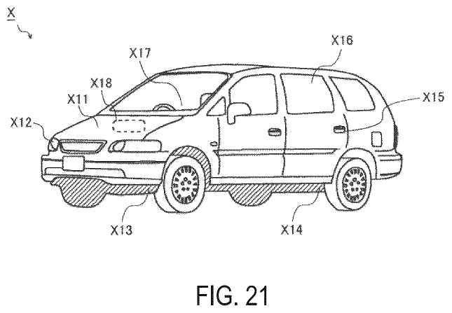

FIG. 21 is an external view showing an example configuration of a vehicle X. The vehicle X of this configuration example is equipped with various electronic equipment X11 to X18 that operate by receiving power supply from an unillustrated battery. Furthermore, mounting positions of the electronic equipment X11 to X18 in FIG. 21 may differ from actual positions for convenience of illustration.

The electronic equipment X11 is an engine control unit that performs control related to an engine (injection control, electronic throttle control, idling control, oxygen sensor heater control, auto cruise control, etc.).

The electronic equipment X12 is a lamp control unit that performs control of turning on and off lights of HID [high intensity discharged lamp], DRL [daytime running lamp], etc.

The electronic equipment X13 is a transmission control unit that performs control related to a transmission.

The electronic equipment X14 is a body control unit that performs control related to a movement of the vehicle X (ABS [anti-lock brake system] control, EPS [electric power steering] control, electronic suspension control, etc.).

The electronic equipment X15 is a security control unit that performs drive control of door locks, security alarms, etc.

The electronic equipment X16 is electronic equipment that is installed in the vehicle X at a time of shipment from a factory as standard equipment or manufacturer option, such as wipers, electric door mirrors, power windows, dampers (shock absorbers), electric sunroofs, electric seats, etc.

The electronic equipment X17 is electronic equipment that is arbitrarily installed in the vehicle X as user options, such as in-vehicle A/V [audio/visual] equipment, a car navigation system, an ETC [electronic toll collection system], etc.

The electronic equipment X18 is electronic equipment that comprises a high-voltage motor, such as an in-vehicle blower, an oil pump, a water pump, a battery cooling fan, etc.

Furthermore, the communication system including the semiconductor device 1 and the motor driver 1001 (I2C device) and the motor 60 described above may be used to drive any of the electronic equipment X11 to X18. Additionally, if the vehicle X is an electric vehicle or a hybrid vehicle, the motor driver 1001 described above can be applied as a means for controlling a motor for driving wheels.

### 8. Other

Furthermore, in addition to the above embodiments, the various technical features disclosed in this specification can be modified in various ways without departing from the spirit of the technical creation. That is, the above embodiments should be considered in all respects as illustrative and not restrictive, and the technical scope of the present disclosure should not be limited to the above embodiments but should be understood to include all modifications that fall within the meaning and scope of claims and equivalents.

### 9. Appendix

As described above, a semiconductor device (1) according to one aspect of the present disclosure is
a semiconductor device connectable to an external transmitting device (20) via a first bus (BS1), and connectable to an external first device (100) via a second bus (BS2), comprising:
a first receiving section (11) configured to be able to receive serial data as reception data (RX) from the transmitting device via the first bus by a first serial communication method;
a first transmitting section (12) configured to be connectable to the first device via the second bus;
a second receiving section (13) configured to be connectable to the first device via the second bus;
a second transmitting section (14) configured to be connectable to the transmitting device via the first bus;
a clock signal output section (16) configured to output a clock signal (SCL) to the first device;
a first output terminal (1C) configured to be connectable to a data terminal (SDA) of the first device; and
a first input terminal (1D) configured to be connectable to the data terminal,
wherein the first receiving section and the first transmitting section are configured such that when a bridge selection data (BR) included in the reception data indicates that a through-output for outputting bit data as is between the first bus and the second bus is on, data (I2CDT) for the first device included in the reception data is through-output from the first output terminal to the second bus,
the clock signal output section is configured to output a clock signal synchronized with the through-output data when the bridge selection data indicates that the through-output is on and communication using a predetermined second serial communication method for the first device is set in the semiconductor device, and
the second receiving section is configured to receive an acknowledgment (ACK) transmitted from the first device via the first input terminal in response to a reception of the through-output data (first configuration).

According to such a configuration, a semiconductor device that can effectively build a communication system together with a device having a communication method different from that of the semiconductor device itself can be provided.

Furthermore, the first configuration may be configured so that the first output terminal and the first input terminal are separate terminals (second configuration).

Furthermore, the first or second configuration may be configured so that in response to a last bit of data bits included in a frame of the reception data, the first transmitting section sets the first output terminal to high impedance and enables the first input terminal to receive the acknowledgment from the first device (third configuration).

Furthermore, the third configuration may be configured so that a number of bits of the data bits provided between a start bit(S) and a stop bit (ST) in the frame is settable (fourth configuration).

Furthermore, any of the first to fourth configurations may be configured so that the semiconductor device comprises a register (151) in which data indicating an anomalous state is stored when the acknowledgment cannot be received (fifth configuration).

Furthermore, any of the first to fifth configurations may be configured so that at a first frame of the reception data that is through-output, a start condition (STA) is generated by a falling edge of data output from the first output terminal and a high level of the clock signal (sixth configuration).

Furthermore, any of the first to sixth configurations may be configured so that after a last frame of the reception data that is through-output, a stop condition (STP) is generated by a rising edge of data output from the first output terminal and a high level of the clock signal (seventh configuration).

Furthermore, any of the first to seventh configurations may be configured so that the clock signal is output such that a rising edge occurs at a center of each bit of data that is through-output from the first output terminal (eighth configuration).

Furthermore, any of the first to eighth configurations may be configured so that when a bit data indicating Read or Write included in the reception data indicates Read, after the through-output of the reception data, transmission data (BTX) read from the first device is through-output to the first bus via the second receiving section and the second transmitting section (ninth configuration).

Furthermore, the ninth configuration may be configured so that at a last frame of the reception data that is through-output, a start condition (STA2) is generated by a falling edge of data output from the first output terminal and a high level of the clock signal (tenth configuration).

Furthermore, the ninth or tenth configuration may be configured so that a start bit and a stop bit are respectively added before and after the transmission data that is through-output, and output to the first bus (eleventh configuration).

Furthermore, any of the ninth to eleventh configurations may be configured so that at a last bit of the transmission data, the data terminal is set to high impedance, and the acknowledgment is output from the first output terminal (twelfth configuration).

Furthermore, any of the ninth to twelfth configurations may be configured so that at a last frame of a frame including the transmission data that is through-output, a stop condition (STP) is generated by a rising edge of data output from the first output terminal and a high level of the clock signal (thirteenth configuration).

Furthermore, any of the first to thirteenth configurations may be configured so that the first serial communication method is UART, and the second serial communication method is I2C (fourteenth configuration).

Furthermore, one aspect of the present disclosure is a communication system (55) comprising the semiconductor device having any of the first to fourteenth configurations, the transmitting device, and the first device (fifteenth configuration).

Furthermore, in the fifteenth configuration, the first device may be configured as a motor driver (1001) (sixteenth configuration).

Furthermore, in the sixteenth configuration, the communication system may be mountable in a vehicle (seventeenth configuration).

### INDUSTRIAL APPLICABILITY

The present disclosure can be utilized, for example, in communication systems for various applications.

1. A semiconductor device, connectable to an external transmitting device via a first bus, and connectable to an external first device via a second bus, comprising:
a first receiving section configured to be able to receive serial data as reception data from the transmitting device via the first bus by a first serial communication method;
a first transmitting section configured to be connectable to the first device via the second bus;
a second receiving section configured to be connectable to the first device via the second bus;
a second transmitting section configured to be connectable to the transmitting device via the first bus;
a clock signal output section configured to output a clock signal to the first device;
a first output terminal configured to be connectable to a data terminal of the first device; and
a first input terminal configured to be connectable to the data terminal,
wherein the first receiving section and the first transmitting section are configured such that when a bridge selection data included in the reception data indicates that a through-output for outputting bit data as is between the first bus and the second bus is on, data for the first device included in the reception data is through-output from the first output terminal to the second bus,
the clock signal output section is configured to output a clock signal synchronized with the through-output data when the bridge selection data indicates that the through-output is on and communication using a predetermined second serial communication method for the first device is set in the semiconductor device, and
the second receiving section is configured to receive an acknowledgment transmitted from the first device via the first input terminal in response to a reception of the through-output data.

2. The semiconductor device of claim 1, wherein the first output terminal and the first input terminal are separate terminals.

3. The semiconductor device of claim 1, wherein in response to a last bit of data bits included in a frame of the reception data, the first transmitting section sets the first output terminal to high impedance and enables the first input terminal to receive the acknowledgment from the first device.

4. The semiconductor device of claim 3, wherein a number of bits of the data bits provided between a start bit and a stop bit in the frame is settable.

5. The semiconductor device of claim 1, comprising a register in which data indicating an anomalous state is stored when the acknowledgment cannot be received.

6. The semiconductor device of claim 1, wherein at a first frame of the reception data that is through-output, a start condition is generated by a falling edge of data output from the first output terminal and a high level of the clock signal.

7. The semiconductor device of claim 1, wherein after a last frame of the reception data that is through-output, a stop condition is generated by a rising edge of data output from the first output terminal and a high level of the clock signal.

8. The semiconductor device of claim 1, wherein the clock signal is output such that a rising edge occurs at a center of each bit of data that is through-output from the first output terminal.

9. The semiconductor device of claim 1, wherein when a bit data indicating Read or Write included in the reception data indicates Read, after the through-output of the reception data, transmission data read from the first device is through-output to the first bus via the second receiving section and the second transmitting section.

10. The semiconductor device of claim 9, wherein at a last frame of the reception data that is through-output, a start condition is generated by a falling edge of data output from the first output terminal and a high level of the clock signal.

11. The semiconductor device of claim 9, wherein a start bit and a stop bit are respectively added before and after the transmission data that is through-output, and output to the first bus.

12. The semiconductor device of claim 9, wherein at a last bit of the transmission data, the data terminal is set to high impedance, and the acknowledgment is output from the first output terminal.

13. The semiconductor device of claim 9, wherein at a last frame of a frame including the transmission data that is through-output, a stop condition is generated by a rising edge of data output from the first output terminal and a high level of the clock signal.

14. The semiconductor device of claim 1, wherein the first serial communication method is UART, and the second serial communication method is I2C.

15. A communication system, comprising the semiconductor device of claim 1, the transmitting device, and the first device.

16. The communication system of claim 15, wherein the first device is configured as a motor driver.

17. The communication system of claim 16, which is mountable in a vehicle.
